(19) United States
(12) Patent Application Publication
(10) Pub. No.: US 2004/0011780 A1
(43) Pub. Date: Jan. 22, 2004

(54) Method for achieving a desired process uniformity by modifying surface topography of substrate heater

(75) Inventors: David P. Sun, Mountain View, CA (US); Steven Gianoulakis, Pleasanton, CA (US)

Correspondence Address: Patent Counsel, M/S 2061, APPLIED MATERIALS, INC., Legal Affairs Department, P.O. Box 450A, Santa Clara, CA, 95052, US

(73) Assignee: Applied Materials, Inc., Santa Clara, CA (US)

(21) Appl. No.: 10/435,121

(22) Filed: May 9, 2003

Related U.S. Application Data
(60) Provisional application No. 60/397,860, filed on Jul. 22, 2002.

(51) Int. Cl. H01L 21/66; H01L 21/477; H01L 21/26; H05B 3/68

(52) U.S. Cl. 219/444.1; 438/14

(57) ABSTRACT

The present invention is directed to achieving a desired process uniformity of processing a substrate which is heated by a heater. In specific embodiments, the method comprises establishing a correlation between a uniformity parameter of the process to be performed on the substrate and a spacing which is disposed between the substrate and a heater surface of the heater facing the substrate. The method further comprises determining a surface profile of the heater surface of the heater facing the substrate, based on the correlation between the uniformity parameter of the process to be performed on the substrate and the spacing between the substrate and the heater surface of the heater, to achieve a preset process uniformity of the uniformity parameter.

### CROSS-REFERENCES TO RELATED APPLICATIONS

This application is based on and claims the benefit of U.S. Provisional Patent Application No. 60/397,860, filed Jul. 22, 2002, the entire disclosure of which is incorporated herein by reference.

### BACKGROUND OF THE INVENTION

The present invention relates generally to a substrate heater for heating substrates and, more particularly, to a method of achieving a desired process uniformity of a layer formed on a substrate which is heated by the substrate heater.

One of the primary steps in the fabrication of modem semiconductor devices is the formation of a thin film on a semiconductor substrate by chemical reaction of gases. Such a deposition process is referred to as chemical vapor deposition (CVD). Conventional thermal CVD processes supply reactive gases to the substrate surface where heat-induced chemical reactions can take place to produce the desired film. Plasma enhanced CVD processes promote the excitation and/or dissociation of the reactant gases by the application of radio frequency (RF) energy to the reaction zone proximate the substrate surface thereby creating a plasma of highly reactive species. The high reactivity of the released species reduces the energy required for a chemical reaction to take place, and thus lowers the required temperature for such CVD processes.

Substrate heaters are used to support and heat a substrate during substrate processing such as the formation of a layer on the substrate. The substrate rests above the heater surface of the heater and heat is supplied to the bottom of the substrate. Some substrate heaters are resistively heated, for example, by electrical heating elements such as resistive coils disposed below the heater surface or embedded in a plate having the heater surface. The heat from the substrate heater is the primary source of energy in thermally driven processes such as thermal CVD for depositing layers including undoped silicate glass (USG), doped silicate glass (e.g., borophosphosilicate glass (BPSG)), and the like. Substrate temperature distribution often affects the process uniformity, such as the film uniformity of a layer formed in the substrate (e.g., film thickness, dopant concentration, refractive index, or the like).

Standard heaters do not employ a vacuum chuck to maintain the substrate on the heater surface. The heater temperature profile of a standard heater typically is highly correlated with the wafer temperature profile, as the heater drives the wafer temperature. The conventional way of affecting wafer temperature uniformity is to change the surface temperature distribution of the heater. To do so, one would redesign the electrical heating element. This is generally an expensive and time-consuming process. In addition, the design of the heating element has certain limitations. For example, due to ceramic cracking problems, a ceramic heater is typically center-hot, which causes the substrate to be center-hot. Such a heater is not suitable for processes in which the substrate should be center-cold or which should have a uniform temperature distribution.

For heaters that employ a vacuum chuck to draw the substrate toward the heater surface by vacuum, some have employed a minimum contact heater to minimize the contact between the heater surface and the substrate in order to reduce film variations. This may be done, for example, by using many vacuum grooves on the heater surface or providing dimples on the heater surface. Heaters with substantially more contact between the heater surface and the substrate are also known. For example, a maximum contact heater has a heater surface that makes substantially full contact with the bottom surface of the substrate. Due to the low pressure gas between the substrate and the heater surface of the heater, the heat transfer from the heater to the substrate is more complex.

### BRIEF SUMMARY OF THE INVENTION

The present invention is directed to achieving a desired process uniformity of a substrate by modifying the distribution of thermal coupling between the substrate and the heater which heats the substrate. The process uniformity is measured by a uniformity parameter, which may be the film uniformity of a layer to be formed on the substrate, such as film thickness, dopant concentration, refractive index, or the like.

In some embodiments, the method modifies the surface topography of the heater surface facing the substrate (i.e., the spacing between the heater surface and the substrate) to control the substrate temperature distribution or other uniformity parameter distribution. This is desirably performed by numerically simulating the process conditions and heat transfer between the heater and the substrate. Based on experimental data correlating the surface topography or spacing of the substrate and the uniformity parameter distribution of the substrate, the uniformity parameter distribution of the substrate can be calculated from the simulated heat transfer between the heater surface having certain surface topography and the substrate. Numerical iteration can be used to adjust the surface topography to obtain the desired uniformity parameter distribution of the substrate.

An aspect of the present invention is directed to a method of achieving a desired process uniformity of processing a substrate which is heated by a heater. The method comprises establishing a correlation between a uniformity parameter of the process to be performed on the substrate and a spacing which is disposed between the substrate and a heater surface of the heater facing the substrate; and determining a surface profile of the heater surface of the heater facing the substrate, based on the correlation between the uniformity parameter of the process to be performed on the substrate and the spacing between the substrate and the heater surface of the heater, to achieve a preset process uniformity of the uniformity parameter.

In accordance with another aspect of the invention, a method of performing a process with a desired uniformity on a substrate comprises providing a heater to heat the substrate in a process chamber. The heater has a heater surface facing the substrate with a surface profile which has been determined to achieve a preset uniformity of a uniformity parameter of a process to be performed on the substrate under a set of process conditions, based on a correlation between the uniformity parameter of the process to be performed on the substrate and a spacing which is disposed between the substrate and the heater surface of the heater facing the substrate. The process is then performed on the substrate having the preset uniformity of the uniformity parameter according to the set of process conditions.

Another aspect of the invention is directed to a method of achieving a desired uniformity of a process to be performed on a substrate which is heated by a heater. The method comprises modifying a heater surface of the heater facing the substrate according to a surface profile which has been determined to achieve a preset uniformity of a uniformity parameter of a process to be performed on the substrate. This is accomplished by performing numerical simulations each by simulating heat transfer between the heater and the substrate for the process to be performed on the substrate, varying the spacing between the substrate and the heater surface of the heater facing the substrate, and calculating the uniformity parameter of the process to be performed on the substrate, based on a correlation between the uniformity parameter of the process to be performed on the substrate and a spacing which is disposed between the substrate and the heater surface of the heater facing the substrate, until the preset uniformity is achieved for a simulated surface profile of the heater.

In accordance with another aspect of the present invention, a heater for heating a substrate in a chamber for forming a layer on the substrate from a process gas comprises a heater surface configured to support the substrate. The heater surface includes a plurality of pockets having an outer pocket and at least one interior pocket. The at least one interior pocket each have a depth which is configured to be spaced from the substrate by greater than an outer depth between a periphery of the substrate and the outer pocket of the heater surface. The plurality of pockets each have a size and a depth previously determined to achieve a preset process uniformity of a uniformity parameter of a process to be performed on the substrate under a set of process conditions, based on a correlation between the uniformity parameter of the process to be performed on the substrate and a spacing which is disposed between the substrate and the heater surface of the heater.

### BRIEF DESCRIPTION OF THE DRAWINGS

FIG. 1 is a simplified sectional view of a conventional heater;

FIG. 2 is a simplified sectional view of a heater according to an embodiment of the present invention;

FIG. 3 is a top plan view of the heater of FIG. 2;

FIG. 4 is a simplified sectional view of a heater according to another embodiment of the present invention;

FIG. 5 is a flow diagram illustrating a method of modifying the surface topography of the heater surface to improve process uniformity according to an embodiment of the invention;

FIG. 6 is a diagram showing simulation results of wafer surface temperature conducted for several heater surface configurations; and

FIG. 7 is a diagram showing experimental results of normalized boron concentration conducted for several heater surface configurations.

### DETAILED DESCRIPTION OF THE INVENTION

Instead of changing the heater element design, the present invention alters the substrate temperature distribution by modifying the distribution of thermal coupling between the heater and the substrate.

For a standard substrate heater with no vacuum chucking, the distribution of thermal coupling between the heater and the substrate is controlled on a region-by-region or spatial basis. The present method contours the substrate temperature distribution for a specific process relatively independent of the heater's heating element design. More specifically, the surface topography of the heater surface of the heater facing the substrate is modified to achieve the desired process uniformity, such as the film uniformity of the layer to be formed on the substrate. The thermal coupling is related to the spacing between the heater surface and the substrate, as well as other factors (e.g., gas type, temperature, and pressure). The desired film uniformity may be measured by a number of uniformity parameters depending on the layer, such as film thickness, dopant concentration, refractive index, or the like. These uniformity parameters are affected by the thermal coupling between the heater and the substrate. The desired uniformity based on the particular uniformity parameter may be achieved by correlating the uniformity parameter with the thermal coupling between the heater and the substrate (as defined by the surface topography of the heater surface) and modifying the surface topography of the heater surface.

This approach has broad applicability in thermal processes such as thermal CVD, but is also applicable to any process that uses a heater to control the substrate temperature. Generally, the approach is most useful where thermal conduction instead of radiation is the primary mode of heat transfer via the gas between the heater and the substrate. Moreover, different surface topography can be used for the same heater element design. This greatly reduces the risk, cost, and lead time to test different iterations. For instance, a heater can have its topography modified and tested at a low cost (e.g., about $1000) in a matter of days. Existing heaters can be retrofitted with a different surface topography as well.

To expedite the surface topography design process, numerical simulations are performed to simulate the process conditions and heat transfer between the heater and the substrate, and obtain a simulated temperature distribution of the substrate for each simulated surface topography design. Based on experimental data correlating the temperature distribution of the substrate and the uniformity parameter distribution of the substrate, the uniformity parameter distribution of the substrate can be calculated from the simulated temperature distribution of the substrate. Numerical iteration can be used to adjust the surface topography to obtain the desired uniformity parameter distribution of the substrate. The surface topography of the heater may then be constructed and tested to confirm the quality of the numerical simulation. This method can predictably manipulate the uniformity parameter such as film thickness or dopant profile to improve the process uniformity of the substrate processing apparatus. The method not only reduces the range of the uniformity parameter to a narrower range, but can manipulate the thermal coupling to achieve a desired uniformity parameter distribution.

The surface topography of the heater surface is modified to alter the thermal coupling between the heater and the substrate, and change the substrate temperature distribution. More specifically, pockets are cut in the heater surface to change the spacing between the heater surface and the substrate to locally cool certain areas of the substrate. In general, the pockets can be any shape and size to achieve a substrate temperature distribution of an almost arbitrary profile for a given heater element design having a given heater temperature distribution. In essence, modifying the surface topography to alter the thermal coupling between the heater and the substrate decouples the heater temperature profile from the substrate temperature profile of a given heater element design. In specific embodiments, the pockets are concentric or annular rings with respect to the center of the heater surface which is aligned with the center of the substrate.

Because the heater surface profile is one of the last steps in heater manufacturing, it is relatively simple to change to provide the surface topography obtained by the present method. Furthermore, the present method provides added flexibility by allowing the heater surface topography design to be “tuned” for specific processes. For example, different carrier gases can affect the thermal conduction and heat transfer between the heater and the substrate. A helium carrier gas is more thermally conductive than an N₂/He carrier gas mixture. The numerical simulation can take this into account in simulating the process conditions and heat transfer between the heater and the substrate.

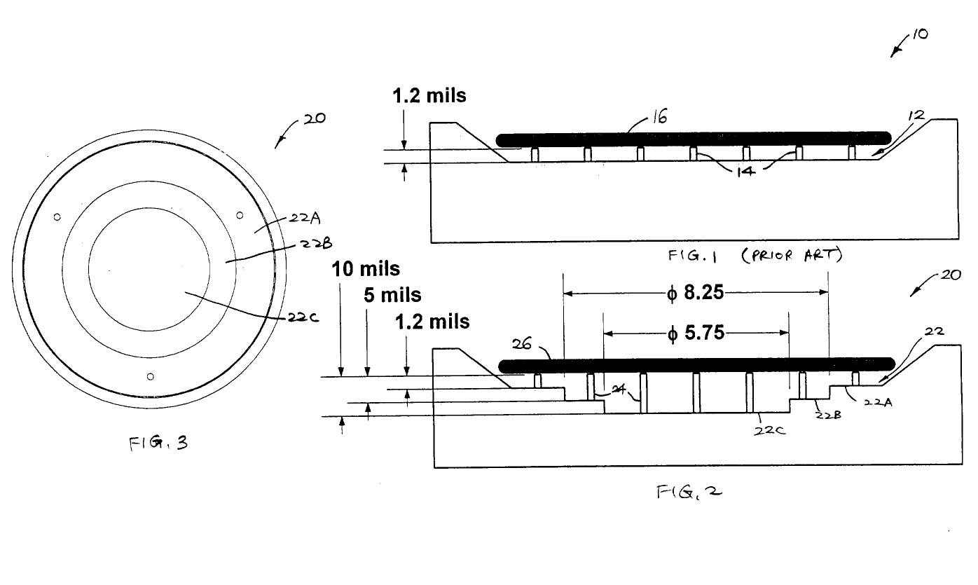

FIG. 1 shows a conventional standard heater 10 having a generally planar heater surface 12. A plurality of posts 14 are used to support the substrate 16 above the heater surface 12. The spacing between the heater surface 12 and the substrate 16 is about 1.2 mils (0.0012 inch) in a specific embodiment. The heater surface 12 as shown does not necessarily heat the substrate 16 evenly, and typically produces a temperature gradient. In addition, variations in the production of heaters may also result in different heating characteristics and profiles.

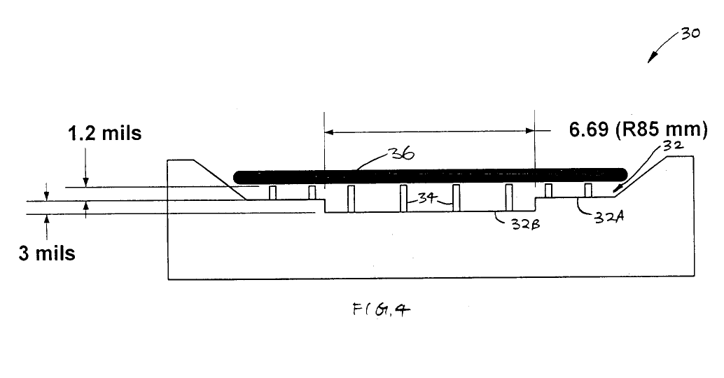

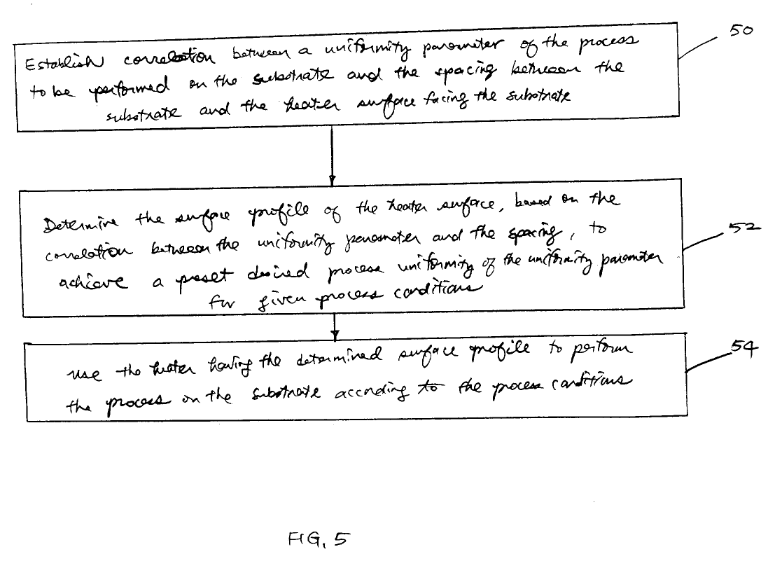

FIGS. 2 and 3 show an example of a heater 20 having three pockets to form a stepped heater surface 22. A plurality of posts 24 support the substrate 26 above the heater surface 22. The pockets are concentric rings cut to form the stepped heater surface 22. Heater surfaces that are made of metal or the like can be reshaped by machining. For ceramic heaters, sandblasting may be used to form pockets with a tolerance of near ±0.001 inch. In this embodiment, the stepped heater surface 22 has three steps or concentric rings. The outer ring or outer pocket 22A extends close to the periphery of the substrate 26 which is about 300 mm (11.8 inch) in diameter, and is spaced from the substrate 26 by a depth of about 1.2 mils. The middle ring 22B has a diameter of about 8.25 inch and a depth of about 5 mils. The inner ring or innermost pocket 22C in a center region of the heater surface has a diameter of about 5.75 inch and a depth of about 10 mils. Each concentric pocket has a constant depth, and increases in depth from the outer pocket 22A to the innermost pocket 22C. Compared to the conventional heater 10 of FIG. 1, this heater 20 has been shown to reduce the substrate temperature range from about 23° C. to about 8° C. in one particular process and the boron concentration range from about 0.31 wt % to about 0.16 wt % in one particular BPSG layer deposition process. It is understood that the pockets may have other shapes and sizes, and need not be axisymmetrical relative to the center to produce concentric rings. In some embodiments, non-axisymmetrical pockets may be used to improve the azimuthal range of the uniformity parameter such as dopant concentration.

FIG. 4 shows another example of a heater 30 having two pockets to form a stepped heater surface 32. A plurality of posts 34 support the substrate 36 above the heater surface 32. The pockets are concentric rings cut to form the stepped heater surface 32. In this embodiment, the stepped heater surface 32 has two steps or concentric rings. The outer ring 32A extends close to the periphery of the substrate 36 which is about 300 mm (11.8 inch) in diameter, and is spaced from the substrate 36 by a depth of about 1.2 mils. The inner pocket 32B has a diameter of about 6.69 inch (or 170 mm) and a depth of about 4.2 mils. In specific embodiments, the innermost pocket has a diameter which is equal to at least about half of the outer diameter of the outer pocket. For instance, the diameter of the innermost pocket 22C in FIG. 2 is approximately equal to about half of the outer diameter of the outer pocket 22A. In FIG. 4, the diameter of the innermost pocket 32B is slightly greater than half of the outer diameter of the outer pocket 32A.

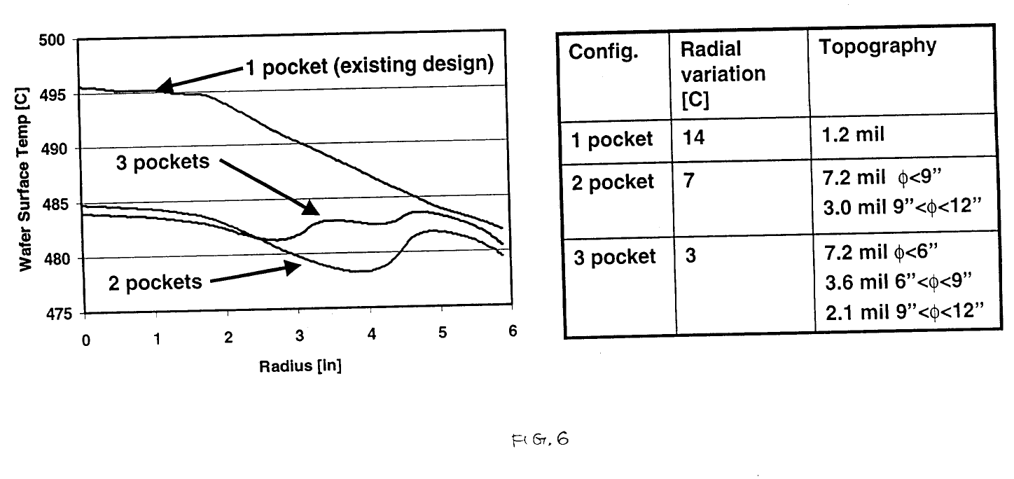

FIG. 5 illustrates the method of modifying the surface topography of the heater surface to improve process uniformity according to an embodiment of the present invention. In step 50, a correlation is established between a uniformity parameter of the process to be performed on the substrate and the spacing between the substrate and the heater surface facing the substrate. To establish the correlation, test data are obtained from a plurality of tests each conducted by performing the process on a substrate while varying the spacing between the substrate and the heater surface. The uniformity parameter is measured, and is correlated with the spacing between the substrate and the heater surface.

In some cases, the uniformity parameter of the process is the substrate temperature. For instance, the thicknesses of some layers such as an undoped silicate glass layer that are formed on the substrate are highly related to the substrate temperature. To obtain a uniform thickness, the substrate temperature should be uniform as well.

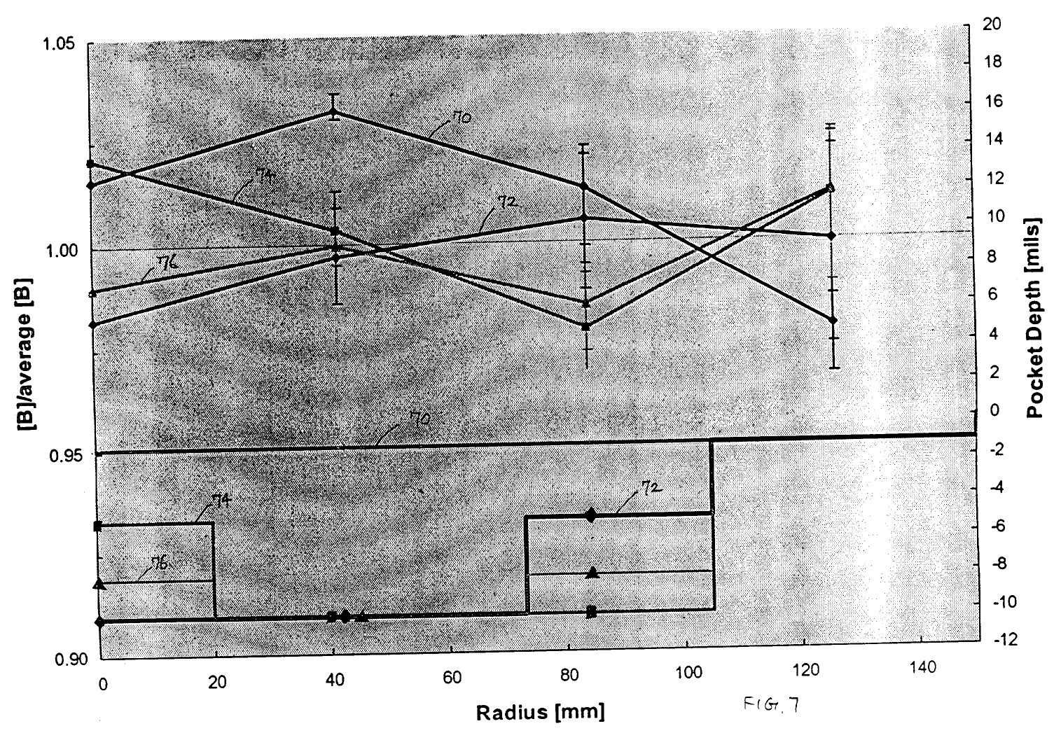

FIG. 6 shows the results of simulations conducted for several heater surface configurations. The experimental data from one or more initial experiments is used to guide the numerical simulation of the process for different heater surface topography, while results of the numerical simulation are used to guide the next experiment(s). This can be repeated until the heater surface topography for producing the desired process uniformity is obtained. The chamber pressure is about 200 Torr, the heater setting is about 480° C., and the gas in the chamber includes N₂. The one-pocket, conventional heater has a depth of about 1.2 mils and is center-hot. The two-pocket heater has an inner pocket of about 9 inches in diameter and about 7.2 mils in depth, and an outer ring of about 9 inches in inner diameter and about 12 inches in outer diameter and about 3 mils in depth. The three-pocket heater has an inner pocket of about 6 inches in diameter and about 7.2 mils in depth; a middle ring of about 6 inches in inner diameter and about 9 inches in outer diameter and about 3.6 mils in depth; and an outer ring of about 9 inches in inner diameter and about 12 inches in outer diameter and about 2.1 mils in depth. Both the two-pocket heater and the three-pocket heater exhibit generally uniform substrate temperature with a range of about 5-6° C. The substrate surface temperature can be measured using any suitable technique, such as an infrared (IR) inspection method.

In some cases, the uniformity parameter of the process is the dopant concentration of a layer formed on the substrate. For instance, the uniformity of boron concentration in a BPSG layer is important to the performance of the layer. While the boron concentration is affected by the substrate temperature, it is not directly or linearly correlated with the substrate temperature so that a uniform substrate temperature does not necessarily produce a uniform boron concentration in the BPSG layer. Other chamber conditions such as gas flow also affect the substrate temperature. Tests were conducted to obtain the correlation between the boron concentration and the spacing between the substrate and the heater surface. The correlation can be used to guide the design of the heater surface topography to achieve a uniform boron concentration. The dopant concentration can be measured using any suitable technique including, for example, x-ray fluorescence (XRF) and Fourier Transformed Infrared Spectroscopy (FTIR).

FIG. 7 shows the result of experiments conducted for several heater surface configurations. The chamber pressure is about 200 Torr, the heater setting is about 480° C., and the gas in the chamber includes He/O₃ (ozone). The one-pocket, conventional heater has a depth of about 1.2 mils and has a peak in boron concentration at about 40 mm from the center and a range of about 0.4 wt % for a 5 wt % film, as represented by plot 70. One three-pocket heater (plot 72) has an inner pocket of about 72 mm in radius and about 10 mils in depth; a middle ring of about 72 mm in inner radius and about 105 mm in outer radius and about 5 mils in depth; and an outer ring of about 105 mm in inner radius and about 150 mm in outer radius and about 1.2 mils in depth. The increase in pocket depth generally lowers the boron concentration radial range, but produces a higher boron concentration near the periphery of the substrate where the pocket is shallower. The boron range is reduced. Another three-pocket heater (plot 74) has an inner pocket of about 20 mm in radius and about 5 mils in depth; a middle ring of about 20 mm in inner radius and about 105 mm in outer radius and about 10 mils in depth; and an outer ring of about 105 mm in inner radius and about 150 mm in outer radius and about 1.2 mils in depth. The increase in pocket depth generally lowers the boron concentration, but again produces a higher boron concentration near the center and the periphery of the substrate where the pockets are shallower. A four-pocket heater (plot 76) has an inner pocket of about 20 mm in radius and about 8 mils in depth; a first middle ring of about 20 mm in inner radius and about 72 mm in outer radius and about 10 mils in depth; a second middle ring of about 72 mm in inner radius and about 105 mm in outer radius and about 8 mils in depth; and an outer ring of about 105 mm in inner radius and about 150 mm in outer radius and about 1.2 mils in depth. The increase in pocket depth generally lowers the boron concentration, but again produces a higher boron concentration near the periphery of the substrate where the pocket is shallower. For plots 72, 74, and 76, the range of boron concentration is reduced from about 0.4 wt % for a 5 wt % film to about 0.26 wt %.

Referring to FIG. 5, the next step 52 after establishing a correlation between the uniformity parameter of the process and the spacing between the substrate and the heater surface is to determine the surface profile of the heater surface, based on the correlation between the uniformity parameter and the spacing, to achieve a preset desired process uniformity of the uniformity parameter for a given set of process conditions. For instance, the preset desired process uniformity may be a substrate temperature range of no more than a maximum range (e.g., 10° C.) when heated to a predetermined temperature or a dopant concentration range of no more than a maximum range (e.g., 0.2 wt %).

Numerical simulation is used to assist in the determination of the surface profile of the heater surface by simulating the process conditions and heat transfer between the heater and the substrate for the process which is to be performed on the substrate. Different surface topography of the heater surface having different pocket configurations and depths can be tried numerically. The uniformity parameter of the process can be calculated from the result of the numerical simulation based on the correlation between the uniformity parameter of the process and the spacing between the heater surface and the substrate, until the preset desired uniformity is achieved for a simulated surface profile of the heater. The experimental data for establishing the correlation between the uniformity parameter and the spacing between the heater surface and the substrate is used to guide the numerical simulation of the process for different heater surface topography.

Any suitable numerical simulation scheme, such as finite elements and the like, may be used. For example, the numerical simulation used to generate the surface topography presented herein is performed using the finite element analysis software ANSYS v5.6.2. A finite element model of the heater, the substrate, and the interfacial gas is constructed. The heat transfer modes included in the model are solid state conduction in the heater and the substrate, and combined stagnant gas conduction and surface-to-surface radiation as the thermal coupling between the heater and the substrate. In some embodiments, convection is neglected in the gas due to the small space between the heater and the substrate. The heater temperature is controlled with a specified radial temperature distribution corresponding to experimental measurements. The boundary conditions from the substrate and heater include convection and radiation to the chamber components.

To produce the desired substrate temperature profile, different pocket configurations are analyzed. The different pocket configurations enter the model through changes in the finite element mesh. After simulating several pocket configurations, a correlation between pocket depth and the effects on substrate temperature is developed. This correlation guides further pocket designs and iterations to produce the desired uniformity parameter profile (e.g., substrate temperature profile, dopant concentration distribution, or the like).

After the surface profile of the heater surface is obtained in step 52 of FIG. 5, the heater having the new surface profile can be used to perform the process on the substrate according to the process conditions (step 54). For example, the process may involve forming a layer on the substrate by introducing a process gas into the process chamber, heating the substrate with the heater, and generating a pressure in the pressure chamber. Additional energy may also be introduced into the process chamber to form the layer. Any suitable apparatus may be used. One example is the Producer Chamber available from Applied Materials, Inc., Santa Clara, Calif. A description of the chamber is found in U.S. Pat. No. 5,855,681, which is incorporated herein by reference in its entirety.

The surface topography of the heater 30 in FIG. 4 is obtained by the method as illustrated in FIG. 5 for forming a BPSG layer in an O₃/He atmosphere, at a chamber pressure of about 200 Torr and a heater setting of about 480° C. The heater 30 has been shown to produce an improved boron concentration uniformity to less than about 0.2 wt %.

The above-described arrangements of apparatus and methods are merely illustrative of applications of the principles of this invention and many other embodiments and modifications may be made without departing from the spirit and scope of the invention as defined in the claims. The scope of the invention should, therefore, be determined not with reference to the above description, but instead should be determined with reference to the appended claims along with their full scope of equivalents.

What is claimed is:

1. A method of achieving a desired process uniformity of processing a substrate which is heated by a heater, the method comprising:
establishing a correlation between a uniformity parameter of the process to be performed on the substrate and a spacing which is disposed between the substrate and a heater surface of the heater facing the substrate; and
determining a surface profile of the heater surface of the heater facing the substrate, based on the correlation between the uniformity parameter of the process to be performed on the substrate and the spacing between the substrate and the heater surface of the heater, to achieve a preset process uniformity of the uniformity parameter.

2. The method of claim 1 wherein the uniformity parameter comprises a dopant concentration in a layer to be formed on the substrate.

3. The method of claim 2 wherein the dopant comprises boron.

4. The method of claim 3 wherein the layer comprises a borophosphosilicate (BPSG) layer.

5. The method of claim 2 wherein the preset uniformity of the uniformity parameter has a range of at most about 0.2 wt % for the dopant concentration in the layer.

6. The method of claim 1 wherein the uniformity parameter comprises a temperature of a layer to be formed on the substrate.

7. The method of claim 1 wherein establishing the correlation between the uniformity parameter of the process to be performed on the substrate and the spacing comprises:
obtaining test data from a plurality of tests each conducted by performing the process on a substrate, varying the spacing between the substrate and the heater surface of the heater facing the substrate, and measuring the uniformity parameter of the process performed on the substrate; and
establishing the correlation between the uniformity parameter of the process performed on the substrate and the spacing based on the obtained test data.

8. The method of claim 1 wherein determining the surface profile of the heater surface of the heater comprises performing numerical simulations each by simulating heat transfer between the heater and the substrate for the process to be performed on the substrate, varying the spacing between the substrate and the heater surface of the heater facing the substrate, and calculating the uniformity parameter of the process to be performed on the substrate, based on the correlation between the uniformity parameter of the process to be performed on the substrate and the spacing, until the preset uniformity is achieved for a simulated surface profile of the heater.

9. The method of claim 1 wherein the heater surface of the heater is axisymmetrical with respect to an axis of the heater.

10. The method of claim 9 wherein the heater surface of the heater comprises a plurality of concentric pockets which are spaced from the substrate by greater spacings than an outer depth between a periphery of the substrate and the heater surface of the heater.

11. A method of performing a process with a desired uniformity on a substrate, the method comprising:
providing a heater to heat the substrate in a process chamber, the heater having a heater surface facing the substrate with a surface profile which has been determined to achieve a preset uniformity of a uniformity parameter of a process to be performed on the substrate under a set of process conditions, based on a correlation between the uniformity parameter of the process to be performed on the substrate and a spacing which is disposed between the substrate and the heater surface of the heater facing the substrate; and
performing the process on the substrate having the preset uniformity of the uniformity parameter according to the set of process conditions.

12. The method of claim 11 wherein performing the process comprises forming a layer on the substrate.

13. The method of claim 12 wherein performing the process comprises introducing a process gas into the process chamber, heating the substrate with the heater, and generating a pressure in the process chamber to form the layer on the substrate, according to the set of process conditions.

14. The method of claim 12 wherein the uniformity parameter comprises a dopant concentration in the layer to be formed on the substrate.

15. The method of claim 11 wherein the heater surface of the heater comprises a plurality of concentric pockets which are spaced from the substrate by greater spacings than an outer depth between a periphery of the substrate and the heater surface of the heater.

16. The method of claim 11 wherein the surface profile of the heater surface of the heater is determined by performing numerical simulations each by simulating heat transfer between the heater and the substrate for the process to be performed on the substrate, varying the spacing between the substrate and the heater surface of the heater facing the substrate, and calculating the uniformity-parameter of the process to be performed on the substrate, based on the correlation between the uniformity parameter of the process to be performed on the substrate and the spacing, until the preset uniformity is achieved for a simulated surface profile of the heater.

17. A method of achieving a desired uniformity of a process to be performed on a substrate which is heated by a heater, the method comprising:
modifying a heater surface of the heater facing the substrate according to a surface profile which has been determined to achieve a preset uniformity of a uniformity parameter of a process to be performed on the substrate, by performing numerical simulations each by simulating heat transfer between the heater and the substrate for the process to be performed on the substrate, varying the spacing between the substrate and the heater surface of the heater facing the substrate, and calculating the uniformity parameter of the process to be performed on the substrate, based on a correlation between the uniformity parameter of the process to be performed on the substrate and a spacing which is disposed between the substrate and the heater surface of the heater facing the substrate, until the preset uniformity is achieved for a simulated surface profile of the heater.

18. The method of claim 17 wherein the correlation between the uniformity parameter of the process to be performed on the substrate and the spacing is determined by obtaining test data from a plurality of tests each conducted by performing the process on a substrate, varying the spacing between the substrate and the heater surface of the heater facing the substrate, and measuring the uniformity parameter of the process.

19. The method of claim 17 wherein the uniformity parameter comprises a dopant concentration in a layer to be formed on the substrate.

20. The method of claim 17 wherein the heater surface of the heater comprises a plurality of concentric pockets which are spaced from the substrate by greater spacings than an outer depth between a periphery of the substrate and the heater surface of the heater.

21. A heater for heating a substrate in a chamber for forming a layer on the substrate from a process gas, the heater comprising:
a heater surface configured to support the substrate, the heater surface including a plurality of pockets having an outer pocket and at least one interior pocket, the at least one interior pocket each having a depth which is configured to be spaced from the substrate by greater than an outer depth between a periphery of the substrate and the outer pocket of the heater surface,
wherein the plurality of pockets each have a size and a depth previously determined to achieve a preset process uniformity of a uniformity parameter of a process to be performed on the substrate under a set of process conditions, based on a correlation between the uniformity parameter of the process to be performed on the substrate and a spacing which is disposed between the substrate and the heater surface of the heater.

22. The heater of claim 21 wherein the plurality of pockets comprise a plurality of concentric pockets which are axisymmetrical with respect to an axis of the heater.

23. The heater of claim 22 wherein each concentric pocket increases in depth from the outer pocket of the heater surface to an innermost pocket in a center region of the heater surface.

24. The heater of claim 23 wherein the innermost pocket has a diameter which is equal to at least about half of an outer diameter of the outer pocket.

25. The heater of claim 22 wherein the heater surface includes at least two interior pockets.

26. The heater of claim 22 wherein each concentric pocket has a constant depth to be spaced from the substrate by a constant spacing.
